(19) United States
(12) Patent Application Publication
(10) Pub. No.: US 2022/0384740 A1
(43) Pub. Date: Dec. 1, 2022

(54) LIGAND MEDIATED LUMINESCENCE ENHANCEMENT IN CYCLOMETALATED RHODIUM(III) COMPLEXES AND THEIR APPLICATIONS IN HIGHLY EFFICIENT ORGANIC LIGHT-EMITTING DEVICES

(71) Applicant: SOUTHERN UNIVERSITY OF SCIENCE AND TECHNOLOGY, Guangdong (CN)

(72) Inventor: Keith Man Chung Wong, Guangdong (CN)

(21) Appl. No.: 17/624,472

(22) PCT Filed: Jul. 4, 2019
(86) PCT No.: PCT/CN2019/094735

§ 371 Date: Jan. 3, 2022

(51) Int. Cl. H01L 51/00; C07F 15/00; C09K 11/06

(52) U.S. Cl. CPC H01L 51/0084; C07F 15/0073; C09K 11/06; C09K 2211/185; C09K 2211/1044; H01L 51/5016

(57) ABSTRACT

A series of highly luminescent cyclometalated rhodium(III) complexes, with photoluminescence quantum yields up to 0.65 in thin films, have been designed and prepared. The strong luminescence property is realized by the judicious choice of a strong σ-donor cyclometalating ligand with lower-lying intraligand state and the ability to raise the d-d excited state. This is the first report to demonstrate the capability of rhodium(III) complexes as high efficient light-emitting materials for organic light-emitting devices. Compelling external quantum efficiencies of up to 12.2% and operational half-lifetime of over 3,000 hours have been achieved.

### TECHNICAL FIELD

The invention relates to fluorescent sensing field. More particularly, a non-fullerene acceptor, which was formed by introduction of chlorine atoms onto the terminal groups of acceptor-donor-acceptor type small molecule electron acceptors, and a polymer derived therefrom.

### BACKGROUND ART

Excited state properties of octahedral d⁶ transition metal complexes, including ruthenium(II),^{[1,2]} rhenium(I),^{[1,3]} osmium(II),^{[1,2,4]} iridium(III)^{[1,5-7]} and rhodium(III),^{[1,8-10]}, have aroused tremendous interests due to their attractive photophysical and photochemical behaviors. From the last two decades, the establishment of the predominant role of luminescent cyclometalated iridium(III) system^{[5-7]} as photo-functional materials has stemmed from their overwhelming properties for the potential biological and energy related applications.^{[6,7]} Since the pioneering work of Thompson, Forrest and coworkers^{[7a]} in employing cyclometalated iridium(III) complexes first reported by Watts^{[5a,b]} as phosphorescent emitters in organic light-emitting devices (OLEDs), promising applications^{[7,11]} have been realized as demonstrated by their rapid adoption in smartphones and displays everywhere.

Being the most important components in OLEDs, there has been a rapid surge of interest in the studies of phosphorescent emitters with heavy metal centers because of their capability to achieve 100% internal quantum efficiency from harvesting the accessible triplet excited state associated with strong spin-orbit coupling (SOC).^{[11]} While most of the related works have been placed with particular emphasis on the use of iridium(III)^{[7,11]} and platinum(II)^{[11,12]} complexes, the use of metal complexes of other transition metals^{[11,13-15]} as emitters has remained a relatively niche topic in order to provide a diversity of OLED materials. Recently, Che^{[16a, b]} and Li[^{16c]} have independently developed different classes of palladium(II) complexes, coordinated to tetradentate ligands with C-deprotonated donor atoms, which have also been demonstrated to be strongly luminescent for the application in OLEDs. This strategy by using not only the strong field ligand but also the rigid scaffold with four coordination sites are anticipated to disfavor the non-radiative deactivation pathway in order to boost up the luminescence properties. Another interesting class is cyclometalated gold(III) complexes, which is isoelectronic and isostructural to the platinum(II) system. Through the choice of strong σ-donating ligand, the gold(III) complexes exhibit strong luminescence properties, as proven by the demonstration of highly efficient OLEDs based on such gold(III) complexes.^{[11,17]} Yam and co-workers have recently pioneered a unique concept of thermally stimulated delayed phosphorescence (TSDP), from which triplet excitons are up-converted from a lower-lying triplet state to a higher-lying triplet state through spin-allowed reverse internal conversion (RIC). This up-conversion process was found to significantly enhance the luminescence quantum yields (Φₗᵤₘ) by over 20-folds.^{[17e]} Similarly, high Φₗᵤₘ could also be obtained through the process of thermally activated delayed fluorescence (TADF) or metal assisted delayed fluorescence (MADF) arising from the reversed intersystem crossing (RISC).^{[18]} In such case, very small energy gap between the lowest singlet state (S₁) and the lowest triplet excited state (T₁) as well as the spatially well-separated frontier orbitals, i.e. highest occupied molecular orbital (HOMO) and lowest unoccupied molecular orbital (LUMO), are required There has recently been a fast-growing interest in the use of TADF/MADF light material for the fabrication of high-efficient OLEDs.^{[15,16c,18]}

Rhodium(III) and iridium(III) are considered as very close congeners in the family of platinum group metals (PGMs) sharing similar synthetic methodology, structural characteristics, and some physical and chemical properties.^{[1,5-10]} On the contrary, the luminescence studies of polypyridyl and cyclometalated rhodium(III) system have been much less explored,^{[8c,9a-c,10]} based on the fact that most of them are only luminescent at low temperature. The related photo-functional application of luminescent rhodium(III) system is also very rare.^{[10c]} This is mainly suffered from the lack of luminescence at room temperature owing to the presence of thermally accessible non-luminescent d-d ligand field (LF) excited state. The presence of LF state at comparable energy to those of the luminescence excited states of ligand-centered (LC) and/or metal-to-ligand charge transfer (MLCT) characters, as revealed by temperature-dependent luminescence lifetime measurements,^{[9d]} remains challenging to be overcome. Through the incorporation of a cyclometalating 1,3-bis(1-isoquinolyl)benzene pincer ligand having the advantages of strong ligand field as well as rigid structural motif, Williams and co-workers have recently synthesized luminescent rhodium(III) complexes with the highest Φₗᵤₘ of up to 10% in solution state at room temperature.^{[10e]}

Although tremendous efforts have been put in to tackle the shortcomings of the luminescence performance of rhodium(III) system, the reported Φₗᵤₘ still could not satisfactorily meet the requirement for OLED application. To the best of our knowledge, rhodium(III) system is up to now the only remaining family member of PGMs for not being utilized as light-emitting material in OLEDs.

### SUMMARY OF THE INVENTION

The inventors develop a series of strongly luminescent cyclometalated rhodium(III) complexes, which satisfactorily meet the requirement for OLED application.

The invention provides a highly luminescent cyclometalated rhodium(III) complex having the formula (a):

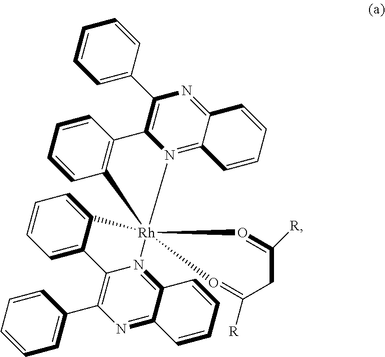

wherein R is an unsubstituted or substituted C₁₋₆ alkyl.

In a preferred embodiment, R is a halogen substituted C₁₋₆ alkyl.

In a more preferred embodiment, R is a fluorine substituted C₁₋₆ alkyl.

In a most preferred embodiment, R is selected from CH₃, CF₃ and C₆F₅.

The invention further provides use of the highly luminescent cyclometalated rhodium(III) complex of the invention as a light-emitting material in OLEDs.

### DESCRIPTION OF FIGURES

FIG. 1 shows (a) molecular structures of 1-3. (b) X-Ray crystal structure of 1. The solvent molecules and hydrogen atoms are omitted, and only the Δ form is shown for clarity.

FIG. 2 shows (a) UV-Vis absorption and emission spectra of complexes 1-3 in dichloromethane solution at 298 K. (b) Normalized PL spectra and PLQY of complexes 1-3 at different excitation wavelengths in solid-state thin film (2 wt % in MCP). Insert shows the photo of thin-film PL of 3 under UV irradiation.

FIG. 3 shows plots of spin density (isovalue=0.002) of the T₁ states of 1-3.

FIG. 4 shows Characteristics of vacuum-deposited OLEDs based on 3. (a) EL spectra with different dopant concentrations. (b) EQEs with different hole-transporting layers. (c) Operational lifetime of the vacuum-deposited OLED made with 5 v/v % 3.

### SPECIFIC EMBODIMENTS

The strongly luminescent cyclometalated rhodium(III) complexes of the invention was demonstrated to be a breakthrough as the first example of a highly efficient rhodium(III) emitter for OLED application. Through the judicious choice of a strong σ-donor cyclometalating ligand with lower-lying intraligand (IL) state, the enhanced luminescence properties of rhodium(III) system from the integration of two strategies, i.e. raising d-d excited state and introduction of lower-lying emissive IL excited state, have been anticipated. The neutral formal charge, high thermal stability and superior Φₗᵤₘ of over 60% in solid-state thin films render these complexes possible for device fabrication by vapor deposition or solution processing technique. Notably, compelling external quantum efficiencies (EQEs) up to 12.2% and fairly respectable operational half-lifetime of over 3,000 hours at 100 cd m-2 in the optimized OLEDs have been achieved from this rhodium(III) system.

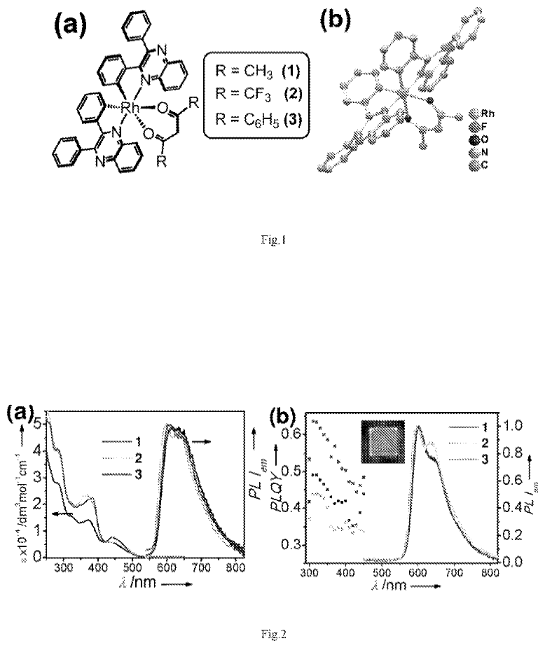

For the introduction of a lower-lying IL state and the maintenance of neutral formal charge in the target complexes 1-3, the cyclometalating ligand of 2,3-diphenylquinoxaline (dpqx) and anionic acetylacetonate (acac) were chosen, respectively. Experimental details of their synthesis and characterizations (¹H, ¹³C{¹H} NMR, HR-MS and elemental analysis) were provided in the Supporting Information. All complexes 1-3 are thermally stable with high decomposition temperatures as revealed by the TGA experiment (Figure S1). The X-ray crystal structure exhibits an octahedral geometry about the rhodium(III) metal center (FIG. 1b and Figure S2) and all the bond lengths and bond angles (See Supporting Information) are within normal ranges.^{[10c,e]}

The photophysical data of 1-3 have been determined and the data are summarized in Table 1. Their UV-vis absorption spectra in fluid solution at 298 K (FIG. 2a) show intense high-energy absorption bands at 335-410 nm and less intense low-energy absorption bands at 420-530 nm. The high-energy absorption bands, which are commonly observed in the related iridium(III) analouges,^{[7d]} are assignable to the spin-allowed singlet intraligand (¹IL) π-π* transitions of the dpqx ligand. The low-energy absorption bands are attributed to the MLCT dπ(Rh)→π*(dpqx) transition, mixed with some IL charge transfer transition from the phenyl moiety to the quinoxaline unit on the dpqx ligand. Unlike most of the rhodium(III) complexes which are essentially non-luminescent, it is noteworthy that the present cyclometalated rhodium(III) complexes show intense orange-red photoluminescence (PL) with peak maxima at 598-612 nm in dichloromethane solutions at 298 K (FIG. 2a). This luminescence is suggested to originated from a triplet parentage, taking into consideration the large Stokes shift and the relatively long luminescence lifetimes (0.79-1.64 μs). In light of the excitation peaks that are resemble the corresponding low-energy absorption bands, the luminescence origin is reasonably assigned as the triplet excited state of MLCT dπ(Rh)→π*(dpqx) origin, with some mixing of intraligand charge transfer (ILCT) character. Nanosecond transient absorption (TA) spectroscopy in dichloromethane solution at 298 K was investigated in order to study the nature of the excited states. From the TA difference spectra of 1-3, two positive absorption bands at 375 nm and 415 nm, assignable to the radical anion absorptions of the cyclometalating ligand, are observed (Figure S3). The TA spectra also showed an additional broad absorption band ranging from 550-775 nm, with the similar lifetimes (0.9-1.7 μs) as their respective PL. These absorption bands are tentatively assigned as absorption from the triplet excited state of MLCT dπ(Rh)→π*(dpqx) origin, with some mixing of ILCT character.

TABLE 1
Photophysical and electrochemical data of 1-3.

| | | Emission | | | | | |
|---|---|---|---|---|---|---|---|
| | Absorption | | 2 wt % doped in | | | | |
| | In CH₂Cl₂ | In CH₂Cl₂ | MCP thin film | Oxidation^{[c]} | Reduction^{[c]} | | |
| | λ_{abs} [nm] | λₑₘ [nm] (Φₛₒₗ [%]^{[a]}; | λₑₘ[nm] (Φ_{film} [%]^{[b]}; | Eₚₐ^{[d]} [V] | E_{1/2}^{[e]} [V] | E_{HOMO}^{[f]} | E_{LUMO}^{[g]} |
| Complex | (ε [dm³ mol⁻¹ cm⁻¹]) | τ[μs]; kᵣ [10⁵ s⁻¹]) | τ[μs]; kᵣ [10⁵ s⁻¹]) | vs. SCE | vs. SCE | [eV] | [eV] |
| 1 | 240 (45535), 285 (27280), | 612 | 603 | +1.32, +1.69 | −1.36, −1.62 | −6.12 | −3.44 |
| | 326 (15130), 375 (13865), | (0.11; 0.79; 0.014) | (49.10; 23; 0.21) | | | | |
| | 455 (5005) | | | | | | |
| 2 | 240 (64940), 259 (51030), | 598 | 597 | +1.63, +2.38 | −1.28, −1.50 | −6.43 | −3.52 |
| | 283 (41085), 383 (22540), | (0.98; 1.64; 0.060) | (44.80; 32; 0.14) | | | | |
| | 441 (7615) | | | | | | |
| 3 | 243 (63715), 262 (52860), | 603 | 602 | +1.38, +1.67 | −1.38, −1.67 | −6.14 | −3.42 |
| | 284 (41315), 370 (24355), | (0.31; 0.81; 0.038) | (65.40; 25; 0.26) | | | | |
| | 455 (5725) | | | | | | |

^{[a]}Luminescence quantum yield Φₛₒₗ, measured at room temperature using [Ru(bpy)₃]Cl₂ in degassed aqueous solution as the reference (λₑₓ = 436 nm, Φₗᵤₘ = 0.042).
^{[b]}Absolute emission quantum yields Φ_{film} in solid-state thin film.
^{[c]}In dichloromethane solution with ⁿBu₄NPF₆ (0.1M) as the supporting electrolyte at room temperature; scan rate 100 mV s⁻¹.
^{[d]}Eₚₐ refers to the anodic peak potential for the irreversible oxidation waves.
^{[e]}E_{1/2} = (Eₚₐ + E_{pc})/2; Eₚₐ and E_{pc} are anodic peak and cathodic peak potentials, respectively.
^{[f]}E_{HOMO} and E_{LUMO} levels were calculated from electrochemical potentials, i.e., E_{HOMO} = −e(4.8 V + E^{ox}ₚₐ); E_{LUMO} = −e(4.8 V + E^{red}_{1/2}).

FIG. 2b depicts the PL spectra of 1-3 in doped N,N-dicarbazolyl-3,5-benzene (MCP) thin films, in which intense orange luminescence of 1-3 at 597-603 nm has been observed (FIG. 2a). In contrast to common square-planar metal complexes which will suffer from triplet-triplet annihilation and π-π interaction between the molecules at high doping concentration, no observable luminescence quenching as well as luminescence peak maxima shift are found in 1-3, upon increasing the doping concentration from 2 to 10 wt % (Figures S4-S6). It is noteworthy that remarkably high Φₗᵤₘ of 0.44-0.65 has been obtained in the doped thin films (FIG. 2b). Nevertheless, to the best of our knowledge, these are the highest Φₗᵤₘ values among all reported rhodium(III) complexes, demonstrating the successful luminescence enhancement by employing a strong σ-donor cyclometalating ligand with lower-lying IL state in metal complexes with octahedral geometry. Variable-temperature PL measurement of 3 was also carried out in thin film from 298 K to 78 K. Upon cooling, the emission peaks remain unchanged except that the vibronic-structured features are becoming more apparent (Figure S7a). In addition, it is found that the emission intensity has been increased by more than two-folds with elongation of lifetimes (Figure S7b). One may argue that the emission in this system may originate from TADF or MADF. The large energy difference between the singlet and triplet states ΔE(S1-T1), from the computational studies (vide infra), indicates that the occurrence of such delayed fluorescence is unlikely.

The electrochemical properties of 1-3 were investigated by cyclic voltammetry and the potentials, together with the estimated HOMO and LUMO energy levels, are tabulated in Table 1. Upon cathodic scan, two quasi-reversible reduction couples are featured at −1.28 to −1.38 V and at −1.50 to −1.67 V (vs. SCE) (Figure S8a), attributed to the successive dqpx ligand-centered reductions. Anodic shifts of the first reduction by about 0.08 V are observed in 2, relative to those in 1 and 3, resulting from the indirect influence upon coordination of the more electron-deficient hexafluoroacetylacetone (hfac) ligand with —CF3 groups. For the anodic scan, the first irreversible anodic peak at +1.32 to +1.63 V (Figure S8b) is attributed to a mixed metal-/ligand-centered oxidation of the rhodium(III) metal center and ligated phenyl ring on dqpx ligand. Similarly, the more positive potential for this oxidation in 2 is due to the lower electron-richness of the rhodium(III) metal center, upon the attachment of the hfac ligand.

In order to gain more insight into the electronic structures as well as the nature of the absorption and emission origins of these rhodium(III) complexes, density functional theory (DFT) and time-dependent DFT (TDDFT) calculations have been performed on 1-3. Summarized in Table S1 are the first fifteen singlet-singlet transitions of 1-3 computed by the TDDFT/CPCM (CH2Cl2) method, and some of the molecular orbitals involved in the transitions are shown in Figures S9-S11. The S0→S1 transitions of 1-3 computed at 467, 455 and 466 nm, respectively, correspond to the HOMO→LUMO excitation. The HOMO is the π orbital localized on the phenyl ring, which is ligated to the rhodium(III) metal center, of the dpqx ligand, with mixing of the dπ(Rh) orbital. The LUMO is mainly the π* orbital on the quinoxaline unit of the dpqx ligand. Therefore, the S0→S1 transition can be assigned as MLCT [dπ(Rh)→π*(dpqx)] transition with mixing of an ILCT [π→π*] transition from the phenyl moiety to the quinoxaline unit of the dpqx ligand, which is in agreement with the experimental energy trend of the low-energy absorption bands and their spectral assignments.

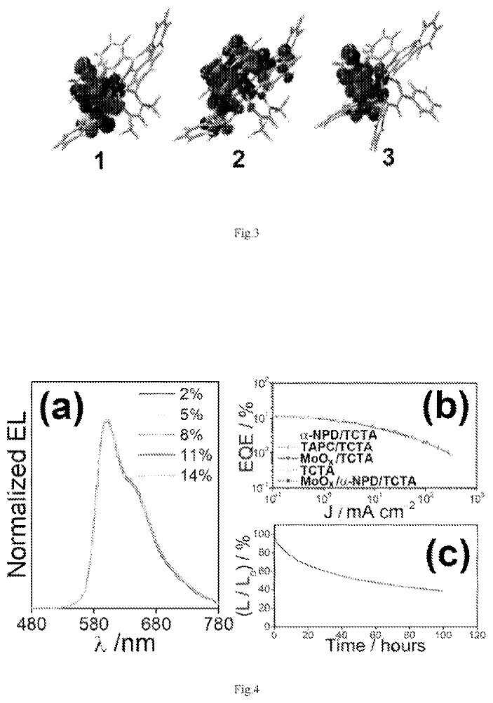

To investigate the nature of the emissive states, geometry optimization on the lowest triplet excited states (T₁) of 1-3 has been performed with the unrestricted method (UPBE0-D3/CPCM). As shown in FIG. 3, the spin density is localized on the metal center, the quinoxaline unit and the ligated phenyl ring of the dpqx ligand, supporting the assignment of emissive states of ³MLCT [dπ(Rh)→π*(dpqx)]/³ILCT [π→π*] character. The computed emission energies of 1-3 (Table S2) are generally over-estimated, yet the trend is well in agreement with the corresponding experimental results, i.e. 1≈3>2. The energy differences between the geometry optimized S₁ and T₁ states of 1-3, ΔE(S₁−T₁), given in Table S3 range from 0.20 to 0.38 eV, indicating a relatively low possibility for TADF to occur.

Solution-processed OLEDs based on 1-3 were prepared for the investigation of the electroluminescence (EL) properties of these rhodium(III) complexes. As shown in Figure S12, all devices display the vibronic-structured EL spectra and are almost identical to their PL spectra in solid-state thin films in the absence of undesired emission from adjacent carrier-transporting or host materials. Similar to the corresponding PL studies, only small changes of ±0.01 in the CIE x and y values for all the devices are observed with increasing dopant concentration from 2 to 10 wt %. Remarkably, satisfactory performance with high maximum current efficiency of 9.4 cd A⁻¹ and EQE of 6.4% is achieved for the optimized device made with 8 wt % 2 (Figure S13). Table S13 summarizes the key parameters for solution-processed devices based on 1-3.

Using 3 with the highest Φₗᵤₘ in solid-state thin film and the highest decomposition temperature, vacuum-deposited OLEDs were also fabricated, in which 3 was doped into MCP at different concentrations (i.e. x=2, 5, 8, 11, and 14 v/v %). Almost identical EL spectra were featured (FIG. 4a) as in the corresponding solution-processed OLEDs. High maximum current efficiency of 9.9 cd A⁻¹ and EQE of 7.0% were achieved for the 5 v/v % doped device (Figure S14). In order to improve the efficiencies, various host materials, including TCTA, m-CBP and Bebq₂, were employed. Remarkably, device efficiencies could be improved to 11.9 cd A⁻¹ and 8.1% when mCBP was used as the host (Figure S15). Further enhancement could be done by either removing the hole-injecting MoOₓ or using a hole-transporting material (HTM) with lower hole mobility (i.e. α-NPD or TCTA). Apparently, the current efficiencies and EQEs could be significantly boosted up to ˜17.5 cd A⁻¹ and ˜12.2%, respectively (FIG. 4b). While TCTA is an excellent electron-blocking material, the insertion of a thin TCTA layer (i.e. 5 nm) at the HTM/emissive interface can effectively accumulate electrons within the emissive layer for exciton formation and light emission. The reduced hole-transport can result in a better balance in the hole and electron currents in the emissive layer and thus improved device efficiency. Tables S14-S16 summarize the key parameters for vacuum-deposited devices based on 3. The operational stability for the vacuum-deposited device based on 3 was also explored. Particularly, the vacuum-deposited device was measured by accelerated testing at a constant driving current density of 20 mA cm⁻². Impressively, the device exhibits an operational half-lifetime (i.e. the time required for the luminance to drop to 50% of its initial value) of ˜52.7 hours at an initial brightness of 1,084 cd m⁻² (FIG. 5c). This corresponds to ˜946 hours at 1,000 cd m⁻² and over 3,000 hours at 100 cd m⁻². The high EQE values and satisfactory operational stability clearly demonstrate the capability of such cyclometalated rhodium(III) complexes serving as promising phosphorescent dopants, and more importantly, this work represents the first successful demonstration of application studies of rhodium(III) complexes in OLEDs.

In summary, we have developed a new class of highly luminescent rhodium(III) complexes in which the luminescence quenching problem from the lowest-lying d-d state is overcome by the incorporation of a strong σ-donor cyclometalating ligand with lower-lying intraligand (IL) state. These complexes exhibit high thermal stability and excellent Φₗᵤₘ as high as up to 0.65 in thin film offering themselves as promising light-emitting materials in OLEDs. Notably, efficient solution-processed and vacuum-deposited OLEDs based on these rhodium(III) complexes with compelling EQEs of 6.4% and 12.2%, respectively, and fairly respectable operational half-lifetime of over 3,000 hours have been realized. This work represents for the first time the application studies of rhodium(III) complexes in OLEDs and opens up a new avenue for diversifying the development of OLED materials, and filling the gap of PGMs with rhodium metal being utilized as phosphors. Apart from the main application of rhodium in catalysis for nitrogen oxides reduction in exhaust gases in catalytic converters for cars, the breakthrough of another potential application of rhodium in OLEDs is demonstrated. Modification of the cyclometalating ligand as well as the ancillary ligand is in progress in order to tune the luminescence color and further improve the EL performance.

In summary, the inventors have developed a new class of highly luminescent rhodium(III) complexes in which the luminescence quenching problem from the lowest-lying d-d state is overcome by the incorporation of a strong σ-donor cyclometalating ligand with lower-lying intraligand (IL) state. These complexes exhibit high thermal stability and excellent Φₗᵤₘ as high as up to 0.65 in thin film offering themselves as promising light-emitting materials in OLEDs. Notably, efficient solution-processed and vacuum-deposited OLEDs based on these rhodium(III) complexes with compelling EQEs of 6.4% and 12.2%, respectively, and fairly respectable operational half-lifetime of over 3,000 hours have been realized. This work represents for the first time the application studies of rhodium(III) complexes in OLEDs and opens up a new avenue for diversifying the development of OLED materials, and filling the gap of PGMs with rhodium metal being utilized as phosphors. Apart from the main application of rhodium in catalysis for nitrogen oxides reduction in exhaust gases in catalytic converters for cars, the breakthrough of another potential application of rhodium in OLEDs is demonstrated. Modification of the cyclometalating ligand as well as the ancillary ligand is in progress in order to tune the luminescence color and further improve the EL performance.

### ACKNOWLEDGEMENTS

K.M.C.W. acknowledges the “Young Thousand Talents Program” award and the start-up fund administered by the Southern University of Science and Technology. This project is also supported by National Natural Science Foundation of China (grant no. 21771099) and Shenzhen Technology and Innovation Committee (grant no. JCYJ20170307110203786 and JCYJ20170817110721105). We gratefully acknowledge Professor Vivian Wing-Wah Yam for access to the equipment for electroluminescence measurements and for her helpful discussion.

### REFERENCES

[1] (a) K. Kalyanasundaram, Photochemistry of Polypyridine and Porphyrin Complexes. Academic Press, London, 1992. (b) V. Balzani, A Juris, M. Venturi, S. Campagna, S. Serroni, Chem. Rev. 1996, 96, 759. (c) V. W. W. Yam, K. M. C. Wong, Chem. Commun. 2011, 47, 11579-11592.
[2] (a) J. P. Sauvage, J. P. Collin, J. C. Chambron, S. Guillerez, C. Coudret, V. Balzani, F Barigelletti, L. De Cola, L. Flamigni, Chem. Rev. 1994, 94, 993-1019. (b) S. Campagna, F. Puntoriero, F. Nastasi, G. Bergamini, V. Balzani, Top. Curr. Chem. 2007, 280, 117-214.
[3] R. A. Kirgan, B. P. Sullivan, D. P. Rillema, Top. Curr. Chem. 2007, 281, 45-100.
[4] D. Kumaresan, K. Shankar, S Vaidya, R. H. Schmehl, Top. Curr. Chem. 2007, 281, 101-142.
[5] (a) R. J. Watts, J Am. Chem. Soc. 1974, 96, 6186-6187. (b) K. A. King, R. J. Watts, J Am. Chem. Soc. 1987, 109, 1589-1590. (c) I. M. Dixon, J. P. Collin, J. P. Sauvage, L. Flamigni, S Encinas, F. Barigelletti, Chem. Soc. Rev. 2000, 29, 385-391. (d) M. S. Lowry, S. Bernhard, Chem. Eur. J. 2006, 12, 7970-7977. (e) L. Flamigni, A Barbieri, C. Sabatini, B. Ventura, F. Barigelletti, Top. Curr. Chem. 2007, 281, 143-203.
[6] (a) K. K. W. Lo, M. W. Louie, K. Y. Zhang, Coord. Chem. Rev. 2010, 254, 2603-2622. (b) K. K. W. Lo, Acc. Chem. Res. 2015, 48, 2985-2995.
[7] (a) M. A. Baldo, S. Lamansky, P. E. Burrows, M. E. Thompson, S. R. Forrest, Appl. Phys. Lett. 1999, 75, 4-6. (b) M. Ikai, S. Tokito, Y Sakamoto, T. Suzuki, Y. Taga, Appl. Phys. Lett. 2001, 79, 156-158. (c) Y. Kawamura, K. Goushi, J. Brooks, J. J. Brown, H. Sasabe, C. Adachi, Appl. Phys. Lett. 2005, 86, 071104/1-3. (d) J. Gao, H. You, J. Fang, D. Ma, L. Wang, X. Jing, F. Wang, Synthetic Metals 2005, 155, 168-171. (e) Y. Sun, N. C. Giebink, H. Kanno, B. Ma, M. E. Thomspon, S. R. Forrest, Nature 2006, 440, 908-912. (f) G. Schwartz, S. Reineke, K. Walzer, K. Leo, Appl. Phys. Lett. 2008, 92, 083301-083301-3. (g) S. Reineke, F. Linder, G. Schwartz, N. Seidler, K. Walzer, B. Lüssem, K. Leo, Nature 2009, 459, 234-238.
[8] (a) P. C. Ford, D. Wink, J. DiBenedetto, Prog. Inorg. Chem. 1983, 40, 213-271. (b) M. J. Hannon, Coord. Chem. Rev. 1997, 162, 477-494. (c) W. Humbs, H. Yersin, Inorg. Chem. 1996, 35, 2220-2228. (d) M. T. Indelli, C. Chiorboli, F. Scandola, Top. Curr. Chem. 2007, 280, 215-255.
[9] (a) Y. Ohsawa, S. Sprouse, K. A. King, M. K. DeArmond, K. W. Hanck, R. J. Watts, J. Chem. Phys. 1987, 91, 1047-1054. (b) M. Maestri, D. Sandrini, V Balzani, U Maeder, A. von Zelewsky, Inorg. Chem. 1987, 26, 1323-1327. (c) D. Sandrini, M. Maestri, V. Balzani, U. Maeder, A. von Zelewsky, Inorg. Chem. 1988, 27, 2640-2643. (d) F. Barigelletti, D. Dandrini, M. Maestri, V. Balzani, A von Zelewsky, L. Chassot, P. Jolliet, U. Baeder, Inorg. Chem. 1988, 27, 3644-3647.
[10] (a) P. Didier, I. Ortmans, A. K. De Mesmaeker, R. J. Watts, Inorg. Chem. 1993, 32, 5239-5245. (b) G. Calogero, G. Giuffrida, S. Serroni, V. Ricevuto, S. Campagna, Inorg. Chem. 1995, 34, 541-545. (c) K. K. W. Lo, C. W. Li, K. W. Lau, N. Zhu, Dalton Trans. 2003, 4682-4689. (d) S. K. Leung, K. Y. Kwok, K. Y. Zhang, K. K. W. Lo, Inorg. Chem. 2010, 49, 4984-4995. (e) L. F. Gildea, A. S. Batsanov, J. A. G. Williams, Dalton Trans. 2013, 42, 10388-10393.
[11] N. Armaroli, H. Bolink, (eds) Photoluminescent Materials and Electroluminescent Devices. Topics in Current Chemistry Collections. Springer, 2017.
[12] (a) B. W. D'Andrade, J. Brooks, V. Adamovich, M. E. Thompson, S. R. Forrest, Adv. Mater. 2002, 14, 1032-1036. (b) Y. Cao, I.D. Parker, G, Yu, C. Zhang, A. J. Heeger, Nature 1999, 397, 414-417. (c) W. Lu, B. X. Mi, M. C. W. Chan, Z. Hui, C. M. Che, N. Zhu, S. T. Lee, J Am. Chem. Soc. 2004, 126, 4958-4971. (d) X.-C. Hang, T. Fleetham, E Turner, J. Brooks, J. Li, Angew. Chem. Int. Ed. 2013, 52, 6753-6756. (f) K. Li, G. S. M. Tong, Q. Wan, G. Cheng, W. Y. Tong, W. H. Ang, W. L. Kwong, C. M. Che, Chem. Sci. 2016, 7, 1653-1673.
[13] (a) F. G. Gao, A. J. Bard, J. Am. Chem. Soc., 2000, 122, 7426-7427. (b) S. Welter, K. Krunner, J. W. Hofstraat, D. De Cola, Nature 2003, 421, 54-57. (c) H. Rudmann, S. Shimada, M. F. Rubner, J Am. Chem. Soc. 2002, 124, 4918-4921.
[14] (a) B. Carlson, G. D. Phelan, W. Kaminsky, L. Dalton, X. Z. S. L. Jiang, A. K. Y. Jen, J. Am. Chem. Soc. 2002, 124, 14162-14172. (b) S. Bernhard, X. Gao, G. G. Malliaras, H. D. Abruna, Adv. Mater. 2002, 14, 433-436. (c) B.-S. Du, J.-L. Liao, M.-H. Huang, C.-H. Lin, H.-W. Lin, Y. Chi, H.-A. Pan, G.-L. Fan, K.-T. Wong, G.-H. Lee, P.-T. Chou, Adv. Fund. Mater. 2012, 22, 3491-3499.
[15] (a) H. Yersin (ed) Highly efficient OLEDs: Materials Based on Thermally Activated Delayed Fluorescence. Wiley-VCH Verlag, 2018. (b) T. Hofbeck, U. Monkowius, H. Yersin, J. Am. Chem. Soc. 2015, 137, 399-404. (c) S. Shi, M. C. Jung, C. Coburn, A. Tadle, S. M. R. Sylvinson, P. I. Djurovich, S. R. Forrest, M. E. Thompson, J Am. Chem. Soc. 2019, 141, 3576-3588.
[16] (a) P.-K. Chow, C. Ma, W.-P. To, G. S.-M. Tong, S.-L. Lai, S. C.-F. Kui, W.-M. Kwok, C.-M. Che, Angew. Chem. Int. Ed. 2013, 52, 11775-11779. (b) P.-K. Chow, G. Cheng, G. S.-M. Tong, C. Ma, W.-M. Kwok, W.-H. Ang, C. Yang, F. Wang, C.-M. Che, Chem. Sci. 2016, 7, 6083-6098. (c) Z.-Q. Zhu, T. Fleetham, E Turner, J. Li, Adv. Mater. 2015, 27, 2533-2537.
[17] (a) K. M. C. Wong, X. Zhu, L. L. Hung, N. Zhu, V. W. W. Yam, H. S. Kwok, Chem. Commun. 2005, 2906-2908. (b) V. K. M. Au, K. M. C. Wong, D. P. K. Tsang, M. Y. Chan, N. Zhu, V. W. W. Yam, J Am. Chem. Soc. 2010, 132, 14273-14278. (c) M. C. Tang, D. P. K. Tsang, M. M. Y. Chan, K. M. C. Wong, V. W. W. Yam, Angew. Chem. Int. Ed. 2013, 52, 446-449. (d) M. C. Tang, D. P. K. Tsang, Y. C. Wong, M. Y. Chan, K. M. C. Wong, V. W. W. Yam, J Am. Chem. Soc. 2014, 136, 17861-17868. (e) M. C. Tang, C. H. Lee, S. L. Lai, M. Ng, M. Y Chan, V. W. W. Yam, J Am. Chem. Soc., 2017, 139, 9341-9349. (e) M. C. Tang, M. Y. Leung, S. L. Lai, M. Ng, M. Y. Chan, V. W. W. Yarn, J Am. Chem. Soc. 2018, 140, 13115-13124. (f) M. C. Tang, C. H. Lee, M. Ng, Y. C. Wong, M. Y. Chang, V. W. W. Yam, Angew. Chem. Int. Ed. 2018, 57, 5463-5466. (g) L. K. Li, M. C. Tang, S. L. Lai, M. Ng, W. K. Kwok, M. Y. Chan, V. W. W. Yam, Nature Photon. 2019, 13, 185-191.
[18] (a) H. Uoyama, K. Goushi, K. Shizu, H. Nomura, C. Adachi, Nature 2012, 492, 234-238. (b) D. M. Zink, M. Bachle, T. Baumann, M. Nieger, M. Kuhn, C. Wang, W. Klopper, U. Monkowius, T. Hofbeck, H. Yersin, S. Brase, Inorg. Chem. 2013, 52, 2292-2305. (c) H. Kaji, H. Suzuki, T. Fukushima, K. Shizu, K. Suzuki, S. Kubo, T. Komino, H. Oiwa, F. Suzuki, A. Wakamiya, Y. Murata, C. Adachi, Nature Commun. 2015, 6, 8476.

1. A highly luminescent cyclometalated rhodium(III) complex having the formula (a): 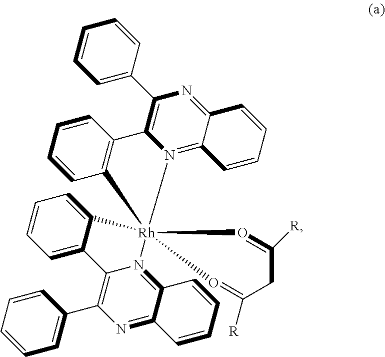
wherein R is an unsubstituted or substituted C1-6 alkyl.

2. The highly luminescent cyclometalated rhodium(III) complex according to claim 1, wherein R is a halogen substituted C1-6 alkyl.

3. The highly luminescent cyclometalated rhodium(III) complex according to claim 1, wherein R is a fluorine substituted C1-6 alkyl.

4. The highly luminescent cyclometalated rhodium(III) complex according to claim 1, wherein R is selected from CH₃, CF₃ and C₆F₅.

5. A light-emitting material in OLEDs derived from the highly luminescent cyclometalated rhodium(III) complex according to claim 1.
